(19) United States
(12) Patent Application Publication
(10) Pub. No.: US 2016/0330874 A1
(43) Pub. Date: Nov. 10, 2016

(54) COOLING DEVICE AND DATA CENTER PROVIDED WITH SAME

(71) Applicant: PANASONIC INTELLECTUAL PROPERTY MANAGEMENT CO., LTD., Osaka (JP)

(72) Inventors: KAORU SATO, Aichi (JP); AYAKA SUZUKI, Aichi (JP)

(21) Appl. No.: 15/110,875

(22) PCT Filed: Jan. 13, 2015
(86) PCT No.: PCT/JP2015/000109

§ 371 Date: Jul. 11, 2016

(30) Foreign Application Priority Data
Jan. 28, 2014 (JP) 2014-012964
Mar. 25, 2014 (JP) 2014-061342

(51) Int. Cl. H05K 7/20; F28D 15/02

(52) U.S. Cl. CPC H05K 7/20818; F28D 15/0275; H05K 7/20409

(57) ABSTRACT

A cooling device has a circulation passage that annularly connects heat receiving part, heat radiation passage, heat radiation part, and feedback passage in order, and working fluid housed in the circulation passage, and check valve provided on an upstream side of heat receiving part. Heat radiation part has a liquefying chamber and a cooling water chamber separated by a partition plate. The liquefying chamber has a first connection part connected to heat radiation passage at an upper part of liquefying chamber, and a second connection part connected to feedback passage at a lower part of liquefying chamber, and has a plurality of first heat radiation fins fixed to the partition plate, and having a plurality of openings or cutouts. The cooling water chamber has a cooling water inlet, a cooling water outlet, and a plurality of second heat radiation fins that separate a passage from the cooling water inlet to the cooling water outlet into a plurality of parallel passages.

### TECHNICAL FIELD

The present invention relates to a cooling device and a data center provided with the same.

### BACKGROUND ART

In electronic devices having large power consumption or power conversion circuits of electric vehicles, a large current of several dozen amperes flows through electronic components such as CPUs and semiconductor switching elements, and therefore large heat is generated in these electronic components.

Conventionally, an electronic component is cooled by a cooling device using a loop type heat pipe (refer to PTL 1, for example).

Hereinafter, the conventional cooling device is described with reference to FIG. 14.

As illustrated in FIG. 14, the loop type heat pipe includes loop circuit 103, heat medium 112, cooler 105, heating part 113, and check valve 114. Loop circuit 103 separately includes riser tube 101 and downcomer 102. Heat medium 112 is working fluid sealed in loop circuit 103 under vacuum. Cooler 105 configures a part of loop circuit 103, and is located at an upper part of loop circuit 103. Heating part 113 is located at a lower part of riser tube 101. Check valve 114 is interposed at a lower part of inside of loop circuit 103, and restricts a circulating direction of heat medium 112 inside loop circuit 103.

Herein, when heat is generated in an electronic component that is brought into contact with heating part 113, the generated heat is transferred to heating part 113 to be added to heat medium 112 circulating through heating part 113, and heat medium 112 is vaporized.

Check valve 107 restricts the circulating direction of heat medium 112. Vaporized heat medium 112 rises through riser tube 101, and is cooled in cooler 105. After condensation, condensed heat medium 112 is liquefied. Additionally, in cooler 105, heat added in heating part 113 is radiated.

Heat medium 112 that radiates heat to be liquefied in cooler 105 comes down through downcomer 102, to return to heating part 113 again through check valve 114.

### CITATION LIST

### Patent Literature

PTL 1:

PTL 1: Unexamined Japanese Patent Publication No. S61-038396

### SUMMARY OF THE INVENTION

In the conventional cooling device, heat exchange pipe 111 for cooling is inserted into cooler 105, and water is supplied to heat exchange pipe 111, as coolant. However, there is a problem that contact probability between vaporized heat medium 112 and heat exchange pipe 111 is low, and cooling capacity in cooler 105 is low.

Additionally, it is necessary to lower a temperature of heat medium 112 that radiates heat to be condensed in cooler 105 in order to cool an electronic component, and the temperature of condensed heat medium 112 is required to be lowered.

An object of the present invention is to lower a temperature of condensed heat medium (hereinafter, working fluid), and enhance cooling capacity.

In order to achieve this object, a cooling device of the present invention cools a rack type server including a plurality of electronic devices. Additionally, the cooling device has: a circulation passage that annularly connects a heat receiving part, a heat radiation passage, a heat radiation part, and a feedback passage in order; working fluid housed in the circulation passage; and a check valve provided on an upstream side of the heat receiving part. The heat radiation part has a liquefying chamber and a cooling water chamber separated by a partition plate. The liquefying chamber has a first connection part connected to the heat radiation passage at an upper part of the liquefying chamber, and a second connection part connected to the feedback passage at a lower part of the liquefying chamber, and has a plurality of first heat radiation fins fixed to the partition plate, and having a plurality of openings or cutouts. The cooling water chamber has a cooling water inlet, a cooling water outlet, and a plurality of second heat radiation fins that separate a passage from the cooling water inlet to the cooling water outlet into a plurality of parallel passages.

Consequently, it is possible to lower a temperature of condensed working fluid to enhance cooling capacity.

That is, in the liquefying chamber of the heat radiation part, vaporized working fluid flows from the first connection part connected to the heat radiation passage to the second connection part connected to the feedback passage. In this liquefying chamber, the working fluid passes from the upper part to the lower part through the openings or the cutouts of the plurality of first heat radiation fins, and gaps between distal ends of the first heat radiation fins and an inner wall of the heat radiation part, to advance from the first connection part side to the second connection part side.

In the cooling water chamber of the heat radiation part, cooling water that flows from the cooling water inlet to the cooling water outlet advances from the cooling water inlet to the cooling water outlet while being separated into the plurality of parallel passages by the plurality of second heat radiation fins.

Therefore, in the liquefying chamber and the cooling water chamber of the heat radiation part, heat transfer from the working fluid and the cooling water to the first and second heat radiation fins is effectively performed.

Then, the openings or the cutouts of the first heat radiation fins inclined upward from the partition plate side are not provided near the partition plate. Therefore, working fluid that comes into contact with the first heat radiation fins to be cooled and condensed flows to the partition plate side in accordance with the inclination of the first heat radiation fins, and is stored near the partition plate.

At this time, the partition plate is cooled by the second heat radiation fins cooled by the cooling water in the cooling water chamber, and therefore the working fluid stayed near the partition plate is cooled up to a temperature lower than a condensation temperature.

Thereafter, the condensed working fluid is further stored, and a water level of the working fluid exceeds that of lower ends of the openings or the cutouts of the first heat radiation fins. At this time, the condense working fluid drops from the openings or the cutouts onto the first heat radiation fins directly below the openings or the cutouts, flows to the partition plate side in accordance with the inclination of the first heat radiation fins, and is stored near the partition plate.

This operation is repeated from the first heat radiation fin at an uppermost stage to the first heat radiation fin at a lowermost stage. Consequently, working fluid that drops from the openings or the cutouts of the first heat radiation fin at the lowermost stage, is stored on a bottom surface of the inside of the liquefying chamber, and is condensed flows to the feedback passage at the temperature lower than the condensation temperature.

Additionally, gaps are provided between distal ends of the first heat radiation fins and an inner wall of the heat radiation part, the inner wall facing the partition plate. Consequently, working fluid that flows into the liquefying chamber from the first connection part side to be vaporized can flow through both the gaps, and the openings or the cutouts of the first heat radiation fins, and a pressure loss can be reduced.

Additionally, an outer periphery of the partition plate can be also welded to an inner surface of the heat radiation part. Consequently, it is possible to maintain a high sealing degree of the inside of the liquefying chamber, and it is also possible to maintain negative pressure of the inside of the circulation passage that houses the working fluid. Therefore, refrigerant can be continuously circulated with a heat quantity of a semiconductor switching element.

### BRIEF DESCRIPTION OF DRAWINGS

FIG. 1 is a schematic diagram of a data center of first and second exemplary embodiments of the present invention.

FIG. 2A is a side view of a cooling device of the first exemplary embodiment of the present invention.

FIG. 2B is a rear view of the cooling device of the first exemplary embodiment of the present invention.

FIG. 3A is a side view of an inner cooling loop of the cooling device of the first exemplary embodiment of the present invention.

FIG. 3B is a configuration diagram illustrating 3B-3B cross-section of FIG. 3A.

FIG. 4A is an internal perspective plan view of a heat radiation part of the cooling device of the first exemplary embodiment of the present invention.

FIG. 4B is a configuration diagram illustrating 4B-4B cross-section of FIG. 4A.

FIG. 5A is a detailed internal perspective side view of the heat radiation part of the cooling device of the first exemplary embodiment of the present invention.

FIG. 5B is a configuration diagram illustrating 5B-5B cross-section of FIG. 5A.

FIG. 5C is an A part detailed view of FIG. 5B.

FIG. 5D is a configuration diagram illustrating 5D-5D cross-section of FIG. 5B.

FIG. 6A is a detailed internal perspective side view of another heat radiation part of the cooling device of the first exemplary embodiment of the present invention.

FIG. 6B is a configuration diagram illustrating 6B-6B cross-section of FIG. 6A.

FIG. 7A is an internal configuration diagram of the heat radiation part of the cooling device of the first exemplary embodiment of the present invention.

FIG. 7B is a side view illustrating a method for manufacturing heat radiation fins of the heat radiation part of the cooling device of the first exemplary embodiment of the present invention.

FIG. 7C is a rear view illustrating a method for manufacturing heat radiation fins of the heat radiation part of the cooling device of the first exemplary embodiment of the present invention.

FIG. 7D is a side view illustrating a method for manufacturing another heat radiation fin of the heat radiation part of the cooling device of the first exemplary embodiment of the present invention.

FIG. 8A is a side view of a cooling device of a second exemplary embodiment of the present invention.

FIG. 8B is a rear view of the cooling device of the second exemplary embodiment of the present invention.

FIG. 9A is a plan view of an inner cooling loop of the cooling device of the second exemplary embodiment of the present invention.

FIG. 9B is a configuration diagram illustrating 9B-9B cross-section of FIG. 9A.

FIG. 10A is an internal perspective plan view of a heat radiation part of the cooling device of the second exemplary embodiment of the present invention.

FIG. 10B is a configuration diagram illustrating 10B-10B cross-section of FIG. 10A.

FIG. 11A is a detailed internal perspective plan view of the heat radiation part of the cooling device of the second exemplary embodiment of the present invention.

FIG. 11B is a configuration diagram illustrating 11B-11B cross-section of FIG. 11A.

FIG. 12A is an internal configuration diagram of the heat radiation part of the cooling device of the second exemplary embodiment of the present invention.

FIG. 12B is a side view illustrating a method for manufacturing heat radiation fins of the heat radiation part of the cooling device of the second exemplary embodiment of the present invention.

FIG. 12C is a rear view illustrating a method for manufacturing the heat radiation part of the cooling device of the second exemplary embodiment of the present invention.

FIG. 12D is a side view illustrating a method for manufacturing different heat radiation fins of the heat radiation part of the cooling device of the second exemplary embodiment of the present invention.

FIG. 13A is a rear view of the heat radiation fin of the heat radiation part of the cooling device of the second exemplary embodiment of the present invention.

FIG. 13B is a rear view of a different heat radiation fin of the heat radiation part of the cooling device of the second exemplary embodiment of the present invention.

FIG. 13C is a rear view of a different heat radiation fin of the heat radiation part of the cooling device of the second exemplary embodiment of the present invention.

FIG. 13D is a rear view of another heat radiation fin of the heat radiation part of the cooling device of the second exemplary embodiment of the present invention.

FIG. 14 is a schematic diagram illustrating a conventional cooling device.

### DESCRIPTION OF EMBODIMENTS

### First Exemplary Embodiment

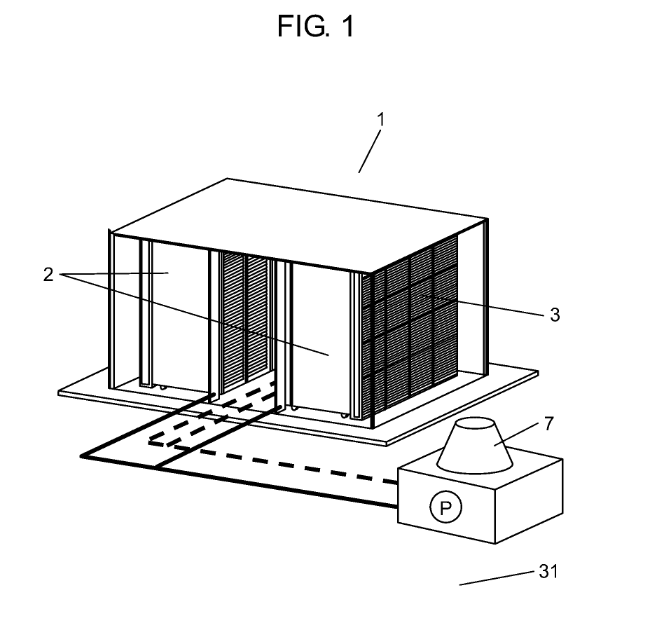

FIG. 1 is a schematic diagram of data center 1 of a first and embodiment of the present invention. Data center 1 in FIG. 1 houses a plurality of rack type servers 2, as a rack type unit.

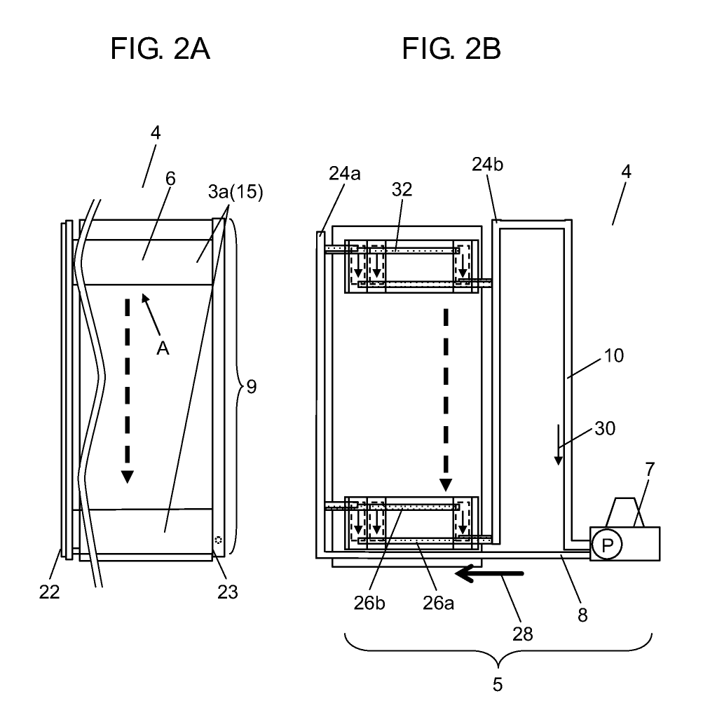

Rack type servers 2 each have housing 22 (refer to FIG. 2A) provided with openings on a front side and a rear side. FIG. 2A is a side view of cooling device 4 of the first exemplary embodiment of the present invention. Rack type servers 2 each include a plurality of electronic devices 3 in racks of vertical respective stages inside housing 22. In a plurality of electronic devices 3, operation panels or displays are directed to the front side. A plurality of electronic devices 3 are provided with power supply lines and wires for connecting electronic devices 3 or connecting electronic device 3 and an external device on the rear side.

All the electronic devices do not always include the operation panels or displays. A plurality of rack type servers 2 are installed in data center 1, and referred to as an electronic computer, a server room, or the like, as a whole.

FIG. 2B is a rear view of cooling device 4 of the first exemplary embodiment of the present invention. Cooling device 4 is configured by outer cooling loop 5 and a plurality of inner cooling loops 6, as illustrated in FIG. 2A and FIG. 2B. Outer cooling loop 5 is a water cooling cycle in which outdoor cooling tower 7, outward water cooling tube 8, water-cooled heat exchanger 9, and return water cooling tube 10 are sequentially connected, and a refrigerant is circulated.

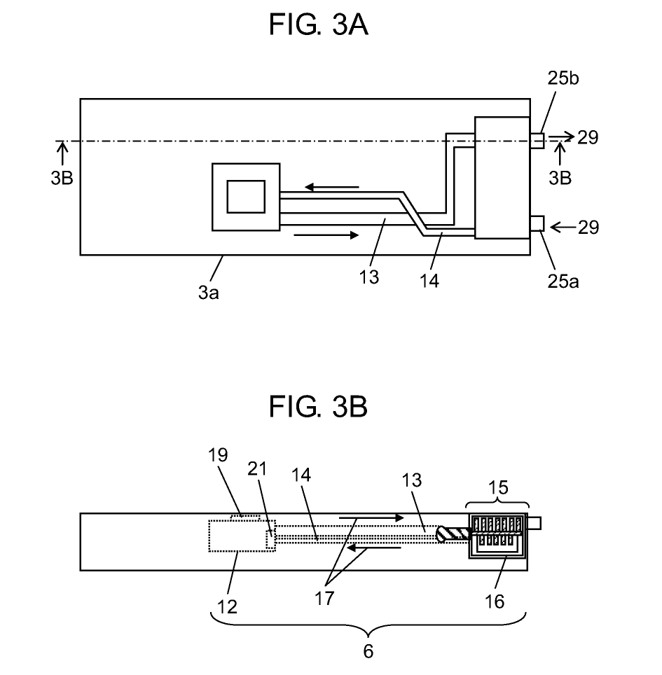

The refrigerant is water. Outward water cooling tube 8 and return water cooling tube 10 connect water-cooled heat exchanger 9 and outdoor cooling tower 7. Water-cooled heat exchanger 9 is provided on rear side 23 of housing 22. Two headers 24a, 24b, cooling water inlet pipes 25a and cooling water outlet pipes 25b (FIG. 3A) that are connected to heat radiation parts 15 of inner cooling loops 6, and flexible tubes 26a, 26b that connect headers 24a, 24b, and cooling water inlet pipes 25a and cooling water outlet pipes 25b are provided.

FIG. 3A is a side view of inner cooling loop 6 of cooling device 4 of the first exemplary embodiment of the present invention. FIG. 3B is a configuration diagram illustrating 3B-3B cross-section of FIG. 3A. As illustrated in FIG. 3A and FIG. 3B, heat receiving part 12, heat radiation passage 13, feedback passage 14, and heat radiation part 15 of inner cooling loop 6 are provided in case 3a. Additionally, heat radiation part 15 is connected to outer cooling loop 5 outside case 3a through cooling water inlet pipe 25a and cooling water outlet pipe 25b. Heat radiation passage 13 and feedback passage 14 connect heat receiving part 12 and heat radiation part 15.

Heat receiving part 12, heat radiation passage 13, heat radiation part 15, and feedback passage 14 are sequentially coupled, so that a circulation passage for allowing working fluid 17 to circulate is formed. Heat of heat receiving part 12 is moved to heat radiation part 15. Check valve 21 is provided between heat radiation part 15 and heat receiving part 12 in the circulation passage.

Air pressure in the circulation passage is determined by working fluid 17 to be used. For example, in a case where working fluid 17 is water, the air pressure is often set to be lower than atmospheric pressure.

Hereinafter, a configuration of each part is described in detail.

As illustrated in FIG. 3A and FIG. 3B, heat receiving part 12 has a box shape and is vertically provided. On a side surface of heat receiving part 12, electronic component 19 (for example, a CPU) that is a heating element is mounted in a state where heat conduction is possible. Heat receiving part 12 transfers heat from electronic component 19 to working fluid 17. Additionally, to the side surface of heat receiving part 12, an end of heat radiation passage 13 and an end of feedback passage 14 are coupled.

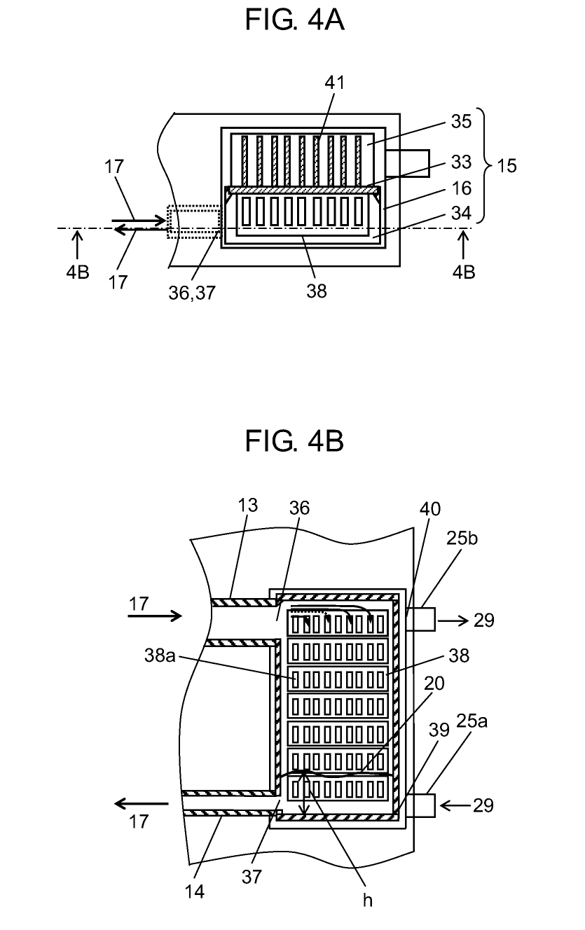

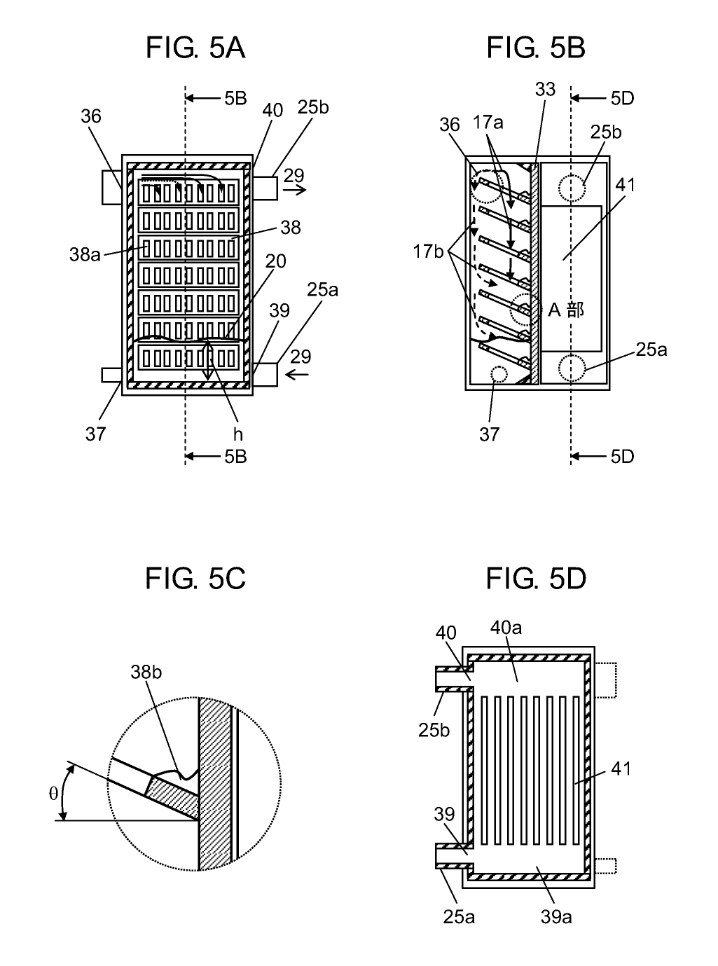

FIG. 4A is an internal perspective plan view of the heat radiation part of cooling device 4 of the first exemplary embodiment of the present invention. FIG. 4B is a configuration diagram illustrating 4B-4B cross-section of FIG. 4A. FIG. 5A is a detailed internal perspective side view of the heat radiation part of cooling device 4 of the first exemplary embodiment of the present invention. FIG. 5B is a configuration diagram illustrating 5B-5B cross-section of FIG. 5A. FIG. 5C is an A part detailed view of FIG. 5B. FIG. 5D is a configuration diagram illustrating 5D-5D cross-section of FIG. 5B.

As illustrated in FIG. 4A, heat radiation part 15 that radiates heat of working fluid 17 has rectangular parallelepiped heat radiation case 16, and partition plate 33 that partitions inside of heat radiation case 16 into right and left parts. Heat radiation part 15 further has liquefying chamber 34 and cooling water chamber 35 disposed at the right and left parts of partition plate 33.

In liquefying chamber 34, first connection part 36 to heat radiation passage 13 is provided at an upper part, and second connection part 37 to feedback passage 14 is provided at a lower part. In liquefying chamber 34, a plurality of first heat radiation fins 38 are provided in a vertical direction of partition plate 33 (seven in this exemplary embodiment). First heat radiation fins 38 each have a plurality of openings 38a (nine in this exemplary embodiment).

Cooling water chamber 35 is provided with cooling water inlet 39 and cooling water outlet 40. Additionally, a plurality of second heat radiation fins 41 that separate a passage from cooling water inlet 39 side to cooling water outlet 40 side into a plurality of parallel passages is provided on cooling water chamber 35 side of partition plate 33. An outer periphery of partition plate 33 is welded to an inner surface of heat radiation case 16.

First heat radiation fins 38 are integrated with a surface, on liquefying chamber 34 side, of partition plate 33 by welding. Second heat radiation fins 41 are integrated with a surface, on cooling water chamber 35 side, of partition plate 33 by welding.

First heat radiation fins 38 each inclines upward from partition plate 33 side by angle θ (refer to FIG. 5C). Second heat radiation fins 41 are disposed so as to be substantially perpendicular to first heat radiation fins 38. Herein, θ is preferably in a range from 5° to 45°.

As illustrated in FIG. 5B, distal ends of first heat radiation fins 38 are disposed apart from an inner wall of heat radiation case 16, from first connection part 36 to second connection part 37. A reason of the above is that a flow passage of working fluid 17 is ensured in addition to a plurality of openings 38a of first heat radiation fins 38

Second heat radiation fins 41 are disposed apart from heat radiation case 16. A reason of the above is that a chamber space is ensured on cooling water inlet 39 side and cooling water outlet 40 side inside cooling water chamber 35 so as not to prevent cooling water 29 from going in/out.

In the above configuration, an action for cooling electronic components 19 by inner cooling loops 6 is described.

As illustrated in FIG. 3B, inner cooling loops 6 each are configured by heat receiving part 12, heat radiation passage 13, heat radiation part 15, and feedback passage 14. For example, working fluid 17 that is water flows through each of inner cooling loops 6. Hereinafter, working fluid 17 is described as water.

In normal operation, water is stored on a bottom surface of liquefying chamber 34 up to liquid level 20 (water level h) illustrated by a wavy line in heat radiation part 15 of FIG. 4B.

When rack type servers 2 illustrated in FIG. 1 are activated, a large current flows in electronic components 19, and heat generation rapidly starts. Then, water in each heat receiving part 12 illustrated in FIG. 3B receives the heat to be drastically boiled and vaporized. The water rushes into liquefying chamber 34 of heat radiation part 15 through heat radiation passage 13. At this time, since check valve 21 exists, the water in heat receiving part 12 does not flow toward feedback passage 14.

As illustrated in FIG. 4A to FIG. 5D, vaporized water that flows from first connection part 36 into an upper part of liquefying chamber 34, namely, vapor comes into contact with first heat radiation fin 38 disposed at an uppermost stage. At the same time, the vaporized water passes through a plurality of openings 38a of first heat radiation fins 38, and a gap between the distal end of first heat radiation fin 38 and the inner wall of heat radiation case 16 to flow toward first heat radiation fin 38 directly below first heat radiation fin 38 at the uppermost stage.

At this time, a part of the vapor that comes into contact with first heat radiation fins 38 becomes condensed water to flow to partition plate 33 side in accordance with inclination of first heat radiation fins 38. Condensed water that does not drop through a plurality of openings 38a is stored in rain-gutter shaped water storage parts 38b formed by partition plate 33 and first heat radiation fins 38.

Herein, in FIG. 5B, flow 17a of vapor that passes through a plurality of openings 38a of first heat radiation fins 38 is illustrated by solid arrows. Flow 17b of vapor that passes through the gap between the distal ends of first heat radiation fins 38 and the inner wall of heat radiation case 16 is illustrated by broken arrows.

Some vapor that passes through a plurality of openings 38a of first heat radiation fin 38 disposed at the uppermost stage, and the gap between the distal end of first heat radiation fin 38 and inner wall of heat radiation case 16 comes into contact with first heat radiation fin 38 disposed at a second stage from a top. Additionally, some vapor passes through a plurality of openings 38a of first heat radiation fins 38, and the gap between the distal end of first heat radiation fin 38 and the inner wall of heat radiation case 16 to flow toward first heat radiation fin 38 directly below first heat radiation fin 38 disposed at the second stage.

At this time, a part of the vapor that comes into contact with first heat radiation fin 38 disposed at the second stage from the top also becomes condensed water. This condensed water flows to partition plate 33 side in accordance with the inclination of first heat radiation fins 38. Condensed water that does not drop through a plurality of openings 38a is stored in rain-gutter shaped water storage parts 38b formed by partition plate 33 and first heat radiation fins 38.

Thus, the vapor that flows from first connection part 36 into an upper part of liquefying chamber 34 flows from the uppermost stage toward a lowermost stage to come into contact with first heat radiation fins 38 at the respective stages, and a part of the vapor becomes condensed water to be stored in rain-gutter shaped water storage parts 38b.

When a water level of the condensed water stored in each of water storage parts 38b is higher than lowermost ends of a plurality of openings 38a of first heat radiation fin 38, condensed water that overflows water storage part 38b flows along partition plate 33 from openings 38a through lower surfaces of first heat radiation fins 38 to drop on water storage part 38b directly below openings 38a.

Thus, condensed water sequentially overflows storage parts 38b disposed at the respective stages. Finally, the condensed water is stored on the bottom surfaces of liquefying chambers 34 to form and maintain water level h of FIG. 5A in liquefying chambers 34.

As illustrated in FIG. 5B, first heat radiation fin 38 disposed at the lowermost stage is located below normal water level h, and therefore is submerged. According to this configuration, a temperature of water that goes from second connection part 37 to feedback passage 14 can be further lower than a condensation temperature.

On the other hand, as illustrated in FIG. 5D, cooling water that passes through cooling water inlet 39 from cooling water inlet pipe 25a to flow into cooling water chamber 35 almost uniformly flows from chamber space 39a on cooling water inlet 39 side to spaces between a plurality of second heat radiation fins 41. The cooling water passes through cooling water outlet 40 from chamber space 40a on cooling water outlet 40 side to flow to cooling water outlet pipe 25b.

At this time, the cooling water cools second heat radiation fins 41. At the same time, the cooling water also cools first heat radiation fins 38 and partition plate 33 that are integrated by welding.

Vapor that flows into liquefying chamber 34 comes into contact with surfaces of cooled first heat radiation fins 38 to be condensed. Consequently, the vapor becomes condensed water. The condensed water is stored in storage parts 38b located at the respective stages, and sequentially overflows storage parts 38b at the respective stages. Finally, the condensed water is stored on the bottom surfaces of liquefying chambers 34 to maintain water level h in normal operation.

Herein, as illustrated in FIG. 4B and FIG. 5A, first heat radiation fins 38 at the respective stages are the same, and openings 38a are disposed at the same positions in the respective stages.

Vapor that flows from first connection part 36 into the upper part of liquefying chamber 34 has a horizontal vector, and therefore hardly passes through openings 38a disposed at the same positions in the respective stages continuously from the top to a bottom. When the vapor comes into contact with first heat radiation fins 38 to pass through openings 38a of first heat radiation fin 38 at the second stage from the bottom, most of the vapor becomes condensed water.

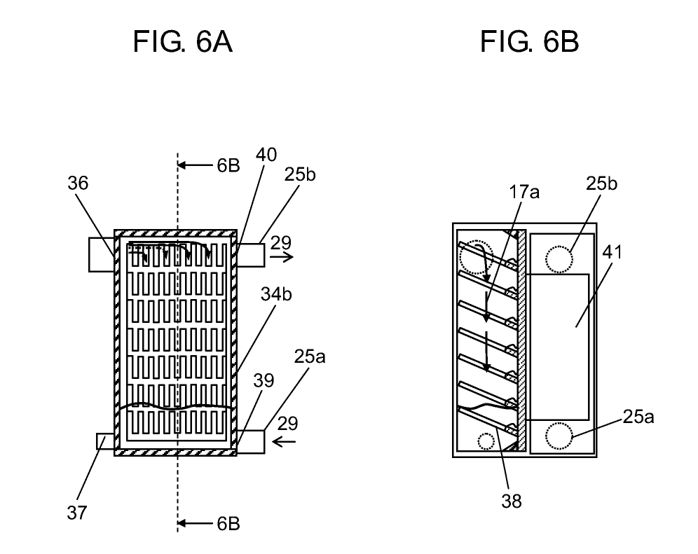

Thus, the condensed water that stays in storage parts 38b comes into contact with partition plate 33 cooled by the cooling water, so that the condensed water is cooled up to a temperature lower than a condensation temperature. Furthermore, the condensed water that is stored on the bottom surfaces of liquefying chambers 34 and has water level h is cooled also by first heat radiation fin 38 disposed at the submerged lowermost stage, and becomes at a lower temperature. In this exemplary embodiment, a case where a plurality of openings 38a are provided in each of first heat radiation fins 38 is described. However, as illustrated in FIG. 6A and FIG. 6B, a cutout can be provided in place of an opening. In this case, the vapor that flows from first connection part 36 into the upper part of liquefying chamber 34 can pass through a vicinity of the distal ends of first heat radiation fins 38, and a vicinity of the inner wall of liquefying chamber 34. Therefore, even when no gap is provided between the distal ends of first heat radiation fins 38 and the inner wall of heat radiation case 16, it is possible to implement a liquefying chamber having a pressure loss that is equal to a pressure loss in a case where a plurality of openings 38a are provided.

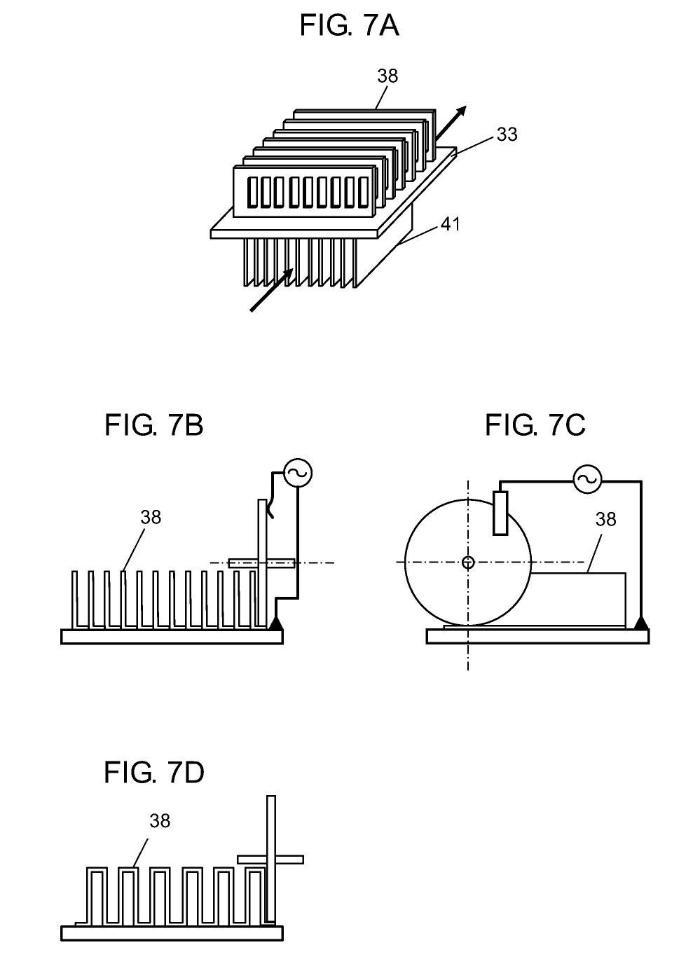

Now, a method for integrating first heat radiation fins 38 and second heat radiation fins 41 with the partition plate by welding is described with reference to FIG. 7A to FIG. 7D. Herein, as materials of first heat radiation fins 38 and second heat radiation fins 41, copper (Cu), aluminum (Al), stainless steel (SUS), or the like is used. However, in a case where working fluid 17 is water, copper is preferable. FIG. 7A is an internal configuration diagram of the heat radiation part of the cooling device of the first exemplary embodiment of the present invention. In FIG. 7A, first heat radiation fins 38 and second heat radiation fins 41 are separately welded at an upper part and a lower part of partition plate 33 respectively in order.

FIG. 7B is a side view illustrating a method for manufacturing the heat radiation fins of the heat radiation part of the cooling device of the first exemplary embodiment of the present invention. In FIG. 7B, the method for manufacturing first heat radiation fins 38 is described below. A plurality of fins having L shaped cross-sections are arranged, and, a roller is used as an electrode, and, for example, an AC voltage is applied to the roller and partition plate 33, so that the plurality of fins having the L shaped cross-sections are integrated by seam welding of continuously welding central parts of short sides of the L-shapes by the roller.

FIG. 7C is a rear view illustrating a method for manufacturing heat radiation fins of the heat radiation part of the cooling device of the first exemplary embodiment of the present invention. FIG. 7C illustrates a case where the fins are formed in square wave shapes. In FIG. 7C, fixing of the fins is easier than fixing of the plurality of fins of FIG. 7B, and a number of processes of welding work can be reduced.

In a case where first heat radiation fins 38 and second heat radiation fins 41 are not integrated with the partition plate by welding, integration by screws is possible. However, when thermal resistance of connection surfaces is considered, integration by welding is preferable.

Then, a method for cooling outer cooling loop 5 that cools cooling water 29 for passing through cooling water pipe 32 to exchange heat with working fluid 17 is described with reference to FIG. 2B.

Cooled outward cooling water 28 is fed from outdoor cooling tower 7, passes through outward water cooling tube 8, and is divided into a plurality of heat radiation parts 15 from header 24a of water-cooled heat exchanger 9. Thereafter, divided cooled outward cooling water 28 converges in header 24b to circulate to return water cooling tube 10.

At this time, cooling water 29 that receives heat from vaporized working fluid 17 which flows through cooling water pipe 32 inside heat radiation part 15 becomes return cooling water 30, and passes through return water cooling tube 10 to be carried to outdoor cooling tower 7. Then, heat from heat radiation parts 15 is radiated to outside air 31, and return cooling water 30 is cooled up to an outside air temperature level.

Return cooling water 30 cooled by outdoor cooling tower 7 becomes outward cooling water 28, and outward cooling water 28 is fed to water-cooled heat exchanger 9 again to take heat from heat radiation parts 15 of inner cooling loops 6. By such circulation, electronic devices 3 are continuously cooled.

As illustrated in FIG. 2B, cooling water 29 that flows in parallel into a plurality of heat radiation parts 15 has a uniform flow rate in each heat radiation part 15. This is because respective flow passage pressure losses in passages from header 24a to header 24b through heat radiation parts 15 are made equal. As a result, all heat radiation parts 15 of water-cooled heat exchanger 9 have the same cooling performance.

Thus, in the data center provided with cooling device 4 that cools each rack type server of the first exemplary embodiment of the present invention, heat taken from heat radiation part 15 of each of inner cooling loops 6 illustrated in FIG. 3B is radiated to outside air 31 from outdoor cooling tower 7, as illustrated in FIGS. 1, 2A, and 2B. Therefore, it is possible to prevent indoor temperature rise caused by exhaust heat of cooling device 4, and increase in power consumption as a whole of data center 1 including an air conditioner is suppressed.

As described above, each of heat radiation parts 15 has partition plate 33 that partitions the inside of heat radiation case 16 into the right and left parts, and liquefying chamber 34 and cooling water chamber 35 that are disposed at the right and left parts of partition plate 33. Condensed water is stayed in the storage parts formed by first heat radiation fins 38 and partition plate 33, for a predetermined time. First heat radiation fin 38 disposed at the lowermost stage is submerged below normal water level h of the condensed water. According to these configurations, condensed water stayed on the bottom surfaces of liquefying chambers 34 is cooled up to a temperature lower than a condensation temperature, and thereafter flows to feedback passage 14. This lowering of the temperature of condensed water in each of feedback passages 14 is effective to automatically lower saturated vapor pressure (saturated vapor temperature) inside liquefying chambers 34 or heat receiving parts 12. Consequently, it is possible to enhance cooling capacity of heat receiving parts 12.

As described above, cooling device 4 of this exemplary embodiment cools rack type servers 1 each including a plurality of electronic devices 3. Additionally, cooling device 4 has a circulation passage that annularly connects heat receiving part 12, heat radiation passage 13, heat radiation part 15, and feedback passage 14 in order, and working fluid 17 housed in the circulation passage, and check valve 21 provided on an upstream side of heat receiving part 12. Heat radiation part 15 has liquefying chamber 34 and cooling water chamber 35 each separated by partition plate 33. Liquefying chamber 34 has first connection part 36 connected to heat radiation passage 13 at an upper part of liquefying chamber 34, and second connection part 37 connected to feedback passage 14 at a lower part of liquefying chamber 34, and has a plurality of first heat radiation fins 38 fixed to partition plate 33, and having a plurality of openings or cutouts. Cooling water chamber 35 has cooling water inlet 39, cooling water outlet 40, and a plurality of second heat radiation fins 41 that separate a passage from cooling water inlet 39 to cooling water outlet 40 into a plurality of parallel passages. Consequently, it is possible to lower a temperature of condensed working fluid 17 to enhance cooling capacity.

In cooling device 4 of this exemplary embodiment, in heat radiation part 15, the inside of the heat radiation case is partitioned into right and left parts by partition plate 33 to be separated into liquefying chamber 34 and cooling water chamber 35. First heat radiation fins 38 are provided in a vertical direction of partition plate 33, and incline upward from partition plate 33. Second heat radiation fins 41 are orthogonal to first heat radiation fins 38. Consequently, it is possible to lower a temperature of condensed working fluid 17 to enhance cooling capacity.

In cooling device 4 of this exemplary embodiment, gaps are provided between the distal ends of first heat radiation fins 38 and the inner wall, facing partition plate 33, of heat radiation part 15. Consequently, working fluid 17 can flow through the gaps, and a pressure loss can be reduced.

In cooling device 4 of this exemplary embodiment, first heat radiation fins 38 are integrated with partition plate 33 by welding. Second heat radiation fins 41 are integrated with partition plate 33 by welding. Consequently, it is possible to efficiently cool first heat radiation fins 38, partition plate 33, and second heat radiation fins 41.

Cooling device 4 of this exemplary embodiment is applicable to data center 1 provided with cooling device 4. Consequently, cooling device 4 is useful for cooling of an electronic device and the like of data center 1.

### Second Exemplary Embodiment

A summary of data center 1 is the same as a summary illustrated in FIG. 1 of the first exemplary embodiment. A plurality of rack type servers 2 are installed in data center 1.

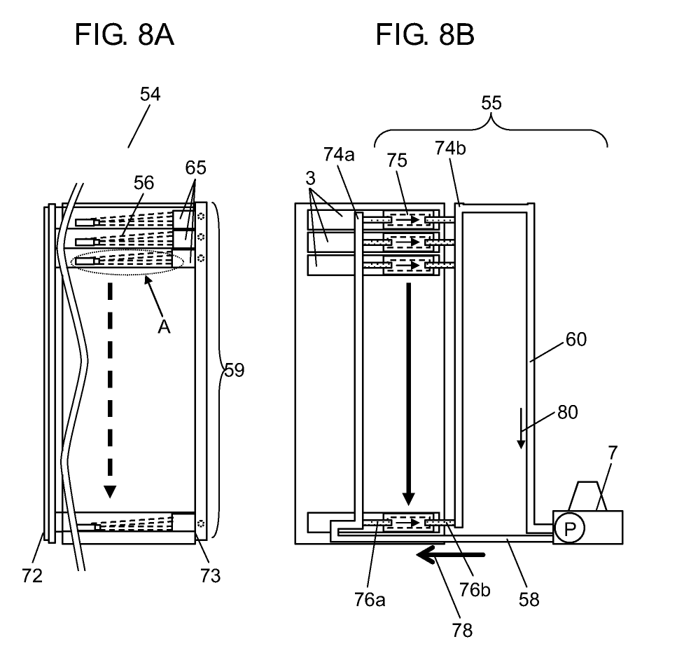

Rack type servers 2 each have housing 72 (refer to FIG. 8A) provided with openings on a front side and a rear side. FIG. 8A is a side view of cooling device 54 of a second exemplary embodiment of the present invention. Rack type servers 2 each include a plurality of electronic devices 3 in a rack manner inside housing 72. In a plurality of electronic devices 3, operation panels or displays are directed to the front side. A plurality of electronic devices 3 are provided with power supply lines and wires for connecting electronic devices 3 or connecting electronic device 3 and an external device on the rear side.

All the electronic devices do not always include the operation panels or displays. A plurality of rack type servers 2 are installed in data center 1, and referred to as an electronic computer, a server room, or the like, as a whole.

FIG. 8B is a rear view of the cooling device of the second exemplary embodiment of the present invention. Cooling device 54 is configured by outer cooling loop 55 and a plurality of inner cooling loops 56, as illustrated in FIG. 8A and FIG. 8B. Outer cooling loop 55 is a water cooling cycle in which outdoor cooling tower 7, outward water cooling tube 58, water-cooled heat exchanger 59, and return water cooling tube 60 are sequentially connected, and a refrigerant is circulated.

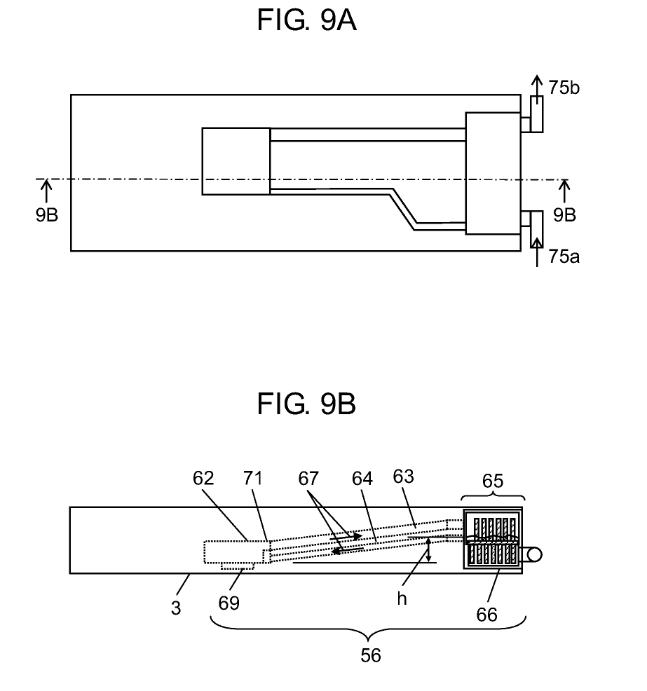

The refrigerant is water. Outward water cooling tube 58 and return water cooling tube 60 connect water-cooled heat exchanger 59 and outdoor cooling tower 7. Water-cooled heat exchanger 59 is provided on rear side 73 of housing 72. Two headers 74a, 74b, cooling water inlet pipes 75a and cooling water outlet pipe 75b (refer to FIG. 9A) that are connected to heat radiation parts 65 of inner cooling loops 56, and flexible tubes 76a, 76b that connect headers 74a, 74b, and cooling water inlet pipes 75a and cooling water outlet pipes 75b are provided.

FIG. 9A is a plan view of inner cooling loop 56 of cooling device 54 of the second exemplary embodiment of the present invention. FIG. 9B is a configuration diagram illustrating 9B-9B cross-section of FIG. 9A. As illustrated in FIG. 9A and FIG. 9B, heat receiving part 62, heat radiation passage 63, and feedback passage 64 of each of inner cooling loops 56 are provided in single electronic device 3. Additionally, heat radiation part 65 is connected to outer cooling loop 55 outside single electronic device 3 through cooling water inlet pipe 75a and cooling water outlet pipe 75b. Heat radiation passage 63 and feedback passage 64 connect heat receiving part 62 and heat radiation part 65.

Heat receiving part 62, heat radiation passage 63, heat radiation part 65, and feedback passage 64 are sequentially coupled, so that a circulation passage for allowing working fluid 67 to circulate is formed. Heat of heat receiving part 62 is moved to heat radiation part 65. Check valve 71 is provided between feedback passage 64 and heat receiving part 62.

Air pressure in the circulation passage is determined by working fluid 67 to be used. For example, in a case where working fluid 67 is water, the air pressure is often set to be lower than atmospheric pressure.

Hereinafter, a configuration of each part is described in detail.

As illustrated in FIG. 9A and FIG. 9B, heat receiving part 62 has a box shape. On a bottom surface of heat receiving part 62, electronic component 69 (for example, a CPU) that is a heating element is mounted in a state where heat conduction is possible. Heat receiving part 62 transfers heat from electronic component 69 to working fluid 67. Additionally, to an upper part or a side surface of heat receiving part 62, an end of heat radiation passage 63, and an end of feedback passage 64 are coupled.

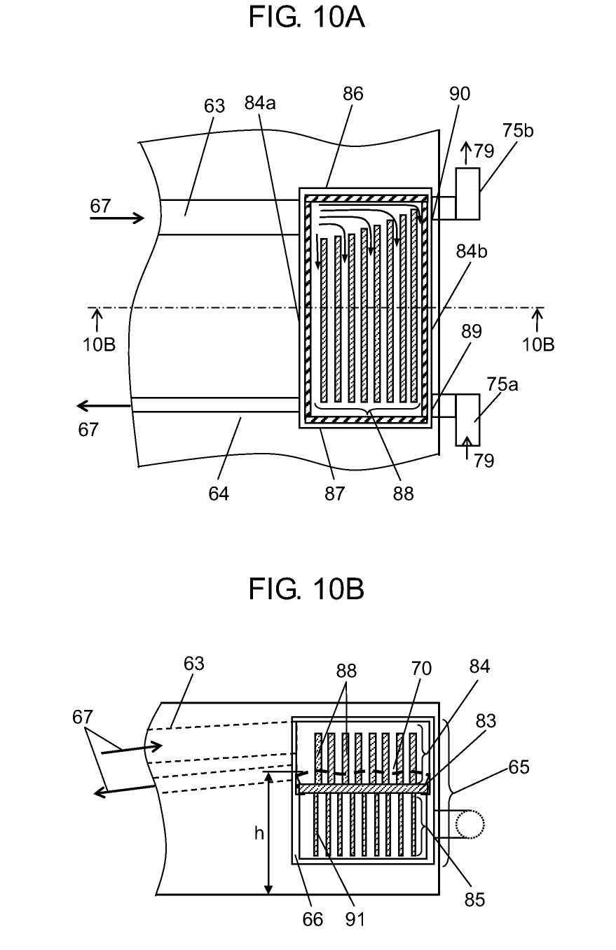

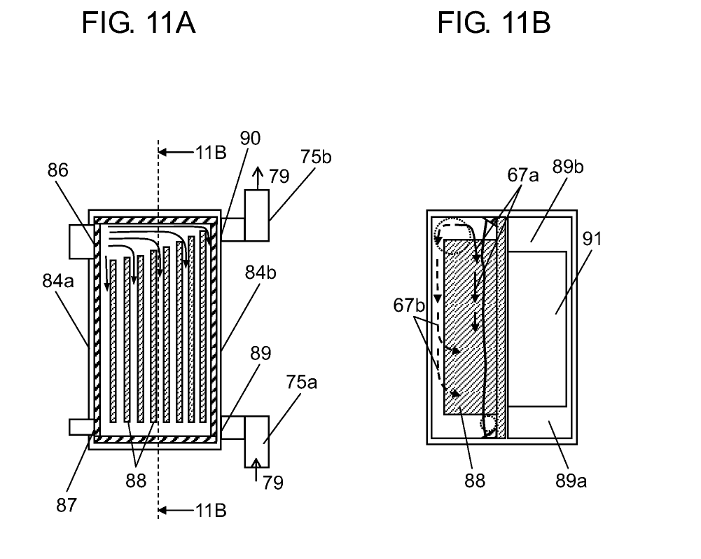

FIG. 10A is an internal perspective plan view of the heat radiation part of cooling device 54 of the second exemplary embodiment of the present invention. FIG. 10B is a configuration diagram illustrating 10B-10B cross-section of FIG. 10A. FIG. 11A is a detailed internal perspective plan view of the heat radiation part. FIG. 11B is a configuration diagram illustrating 11B-11B cross-section of FIG. 11A.

As illustrated in FIG. 10A and FIG. 10B, heat radiation part 65 that radiates heat of working fluid 67 has rectangular parallelepiped heat radiation case 66, and partition plate 83 that vertically partitions inside of heat radiation case 66. Heat radiation part 65 further has liquefying chamber 84 and cooling water chamber 85 disposed at upper and lower parts of partition plate 83, respectively.

In liquefying chamber 84, first connection part 86 to heat radiation passage 63 is provided at an upper part, and second connection part 87 to feedback passage 64 is provided at a lower part. In liquefying chamber 84, a plurality of first heat radiation fins 88 that separate a passage from first connection part 86 to second connection part 87 into a plurality of parallel passages are provided on liquefying chamber 84 side of partition plate 83.

An upper end of partition plate 83 is located below a lower end of second connection part 87.

Cooling water chamber 85 is provided with cooling water inlet 89 and cooling water outlet 90. Additionally, a plurality of second heat radiation fins 91 that separate a passage from cooling water inlet 89 side to cooling water outlet 90 side into a plurality of parallel passages is provided on cooling water chamber 85 side of partition plate 83. An outer periphery of partition plate 83 is weld to an inner surface of heat radiation case 66.

First heat radiation fins 88 are integrated with a surface, on liquefying chamber 84 side, of partition plate 83 by welding. Second heat radiation fins 91 are integrated with a surface, on cooling water chamber 85 side, of partition plate 83 by welding.

First heat radiation fins 88 are disposed in parallel to a surface of inside of liquefying chamber 84, which is provided with first connection part 86 and second connection part 87. Second heat radiation fins 91 are disposed so as to be substantially parallel to first heat radiation fins 88.

As illustrated in FIG. 10A, first heat radiation fins 88 are disposed apart from heat radiation case 66 such that a longitudinal length increases toward a back side of heat radiation case 66 from the first connection part side. A reason of the above is because a flow passage of working fluid 67 is ensured near first connection part 86 side in liquefying chamber 84 and near partition plate 83.

That is, ends, on second connection part 87 side, of first heat radiation fins 88 are disposed at an equal distance from one surface 84a inside liquefying chamber 84. On the other hand, ends, on first connection part 86 side, of first heat radiation fins 88 are formed such that a distance from facing surface 84b of one surface 84a inside liquefying chamber 84 is sequentially reduced from first connection part 86 side.

Second heat radiation fins 91 are disposed apart from heat radiation case 66. A reason of the above is because chamber spaces are ensured on cooling water inlet 89 side and cooling water outlet 90 side inside cooling water chamber 85 so as not to prevent cooling water 79 from going in/out.

In the above configuration, an action for cooling electronic components 69 by inner cooling loops 56 is described.

As illustrated in FIG. 9B, inner cooling loops 56 each are configured by heat receiving part 62, heat radiation passage 63, heat radiation part 65, and feedback passage 64. For example, working fluid 67 that is water flows through each of inner cooling loops 56. Hereinafter, working fluid 67 is described as water.

In normal operation, water is stored on partition plate 83 up to liquid level 70 (water level h) illustrated by a wavy line in heat radiation part 65 of FIG. 10B.

When rack type servers 2 illustrated in FIG. 1 are activated, a large current flows in electronic components 69, and heat generation rapidly starts. Then, water in each heat receiving part 62 illustrated in FIG. 9B receives the heat to be drastically boiled and vaporized. The water rushes into liquefying chamber 84 of heat radiation part 65 through heat radiation passage 63. At this time, since check valve 71 exists, the water in heat receiving part 62 does not flow toward feedback passage 64.

As illustrated in FIG. 10A to FIG. 11A, vaporized water that flows from first connection part 86 into an upper part of liquefying chamber 84, namely, vapor flows almost straight while expanding also downward, in a space as a flow passage of vapor, the space being provided near first connection part 86 side. Additionally, this space becomes narrowed toward a back side of heat radiation case 66 by a difference in lengths of first heat radiation fins 88. Therefore, the vapor almost uniformly flows between a plurality of first heat radiation fins 88 to flow to second connection part 87 side.

On the other hand, as illustrated in FIG. 11A and FIG. 11B, cooling water that flows from cooling water inlet pipe 75a passes through cooling water inlet 89 to flow into cooling water chamber 85. The cooling water that flows into cooling water chamber 85 almost uniformly flows from chamber space 89a on cooling water inlet 89 side to spaces between a plurality of second heat radiation fins 91. Thereafter, the cooling water passes through cooling water outlet 90 from chamber space 89b on cooling water outlet 90 side to flow to cooling water outlet pipe 75b.

At this time, the cooling water cools second heat radiation fins 91. Additionally, the cooling water also cools partition plate 83 and first heat radiation fins 88 that are integrated by welding.

When flowing between cooled first heat radiation fins 88, vapor that flows into liquefying chamber 84 comes into contact with fin surfaces to be condensed, so that the vapor becomes condensed water. The condensed water flows along the fin surfaces to be stored on partition plate 83.

Herein, as illustrated in FIG. 10B, a height of an upper end of partition plate 83 is set to be lower than a lower end of second connection part 87, so that the condensed water stored on partition plate 83 can be stayed for a predetermined time. At this time, the condensed water is stayed on partition plate 83 cooled by cooling water 79, so that the condensed water flows out to feedback passage 64 from second connection part 87 after being cooled to a temperature lower than the condensation temperature.

Thus, the condensed water stayed on partition plate 83 is cooled up to the temperature lower than the condensation temperature, so that a saturated vapor temperature of a part from a boiling part to the liquefying chamber through the heat radiation passage is lowered. Therefore, a temperature of heat receiving part 62 is also lowered, and ability to cool electronic component 69 can be enhanced.

Furthermore, a flow of working fluid 67 inside liquefying chamber 84 is described with reference to FIG. 11A and FIG. 11B.

As described above, the vapor that flows from first connection part 86 to the upper part of liquefying chamber 84 tries to flow in between a plurality of first heat radiation fins 88, as illustrated by solid arrows of FIG. 11A. At this time, the number of first heat radiation fins 88 needs to be increased in order to increase a heat exchange area, and flow passages between first heat radiation fins 88 are narrowed.

Herein, as illustrated in FIG. 11B, spaces for allowing vapor to flow is provided between first heat radiation fins 88 and a ceiling surface of inside of liquefying chamber 84. Therefore, vapor that cannot flow in between a plurality of first heat radiation fins 88 passes between first heat radiation fins 88 and the ceiling surface of the inside of liquefying chamber 84 to flow toward second connection part 87 (broken arrows).

On the other hand, while advancing as illustrated by the solid arrows, lower vapor 67a, which flows in between a plurality of first heat radiation fins 88 comes into contact with first heat radiation fins 88 to be cooled. At the same time, lower vapor 67a becomes condensed water, and drops. The condensed water accumulates on partition plate 83 to advance to a middle of a longitudinal direction of each of first heat radiation fins 88, and all the condensed water drops.

As a result, in a space on second connection part 87 side with respect to the middle of the longitudinal direction of each of first heat radiation fins 88, vapor to be condensed does not exist, and is cooled compared to first connection part 86 side, and pressure is also lowered. Therefore, as illustrated by the broken arrows, upper vapor 67b between first heat radiation fins 88 and the ceiling surface of the inside of liquefying chamber 84 is sucked between first heat radiation fins 88.

Thereafter, upper vapor 67b sucked between first heat radiation fins 88 comes into contact with first heat radiation fins 88 to be cooled, and becomes condensed water to drop and be accumulated on partition plate 83, in a similar manner to a case of first connection part 86 side.

That is, the vapor in liquefying chamber 84 is divided into lower vapor 67a that flows in between first heat radiation fins 88, and upper vapor 67b that flows on a side of the ceiling of the inside of liquefying chamber 84, to flow toward second connection part 87. Vapor on first connection part 86 side of first heat radiation fins 88 exchanges heat with lower vapor 67a. Vapor on second connection part 87 side of first heat radiation fins 88 exchanges heat with upper vapor 67b. Consequently, first heat radiation fins 88 condense lower vapor 67a and upper vapor 67b. That is, surfaces of all first heat radiation fins 88 in liquefying chamber 84 can function as condensation fins.

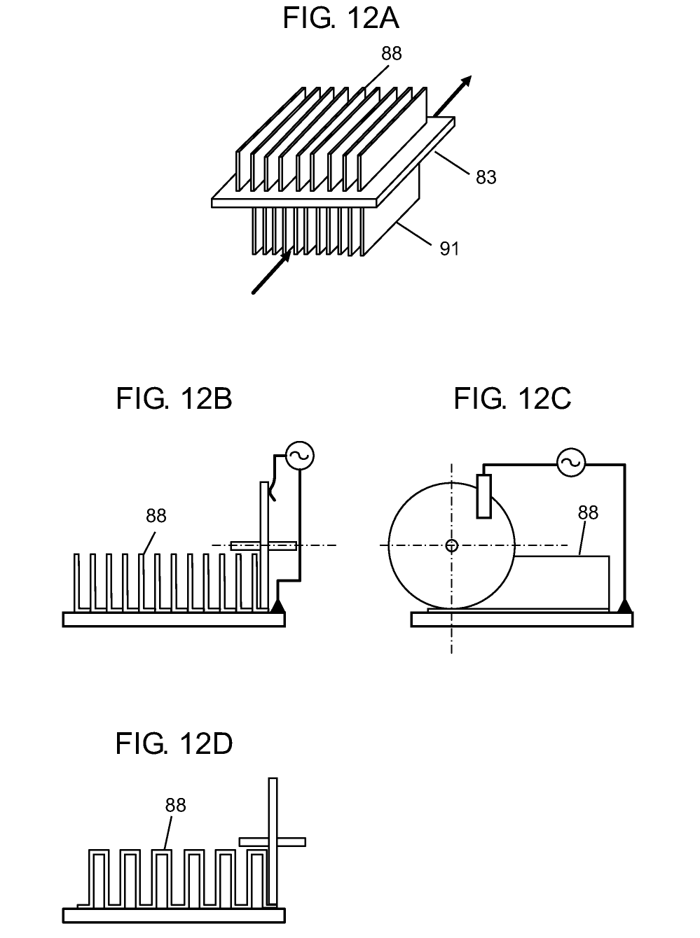

Now, a method for integrating first heat radiation fins 88 and second heat radiation fins 91 with the partition plate by welding is described with reference to FIG. 12A to FIG. 12D. Herein, as materials of first heat radiation fins 88 and second heat radiation fins 91, copper (Cu), aluminum (Al), stainless steel (SUS), or the like is used. However, in a case where working fluid 67 is water, copper is preferable. FIG. 12A is an internal configuration diagram of the heat radiation part of the cooling device of the second exemplary embodiment of the present invention. In FIG. 12A, first heat radiation fins 88 and second heat radiation fins 91 are separately welded at an upper part and a lower part of partition plate 83 in order.

FIG. 12B is a side view illustrating a method for manufacturing the heat radiation fins of the heat radiation part of the cooling device of the second exemplary embodiment of the present invention. In FIG. 12B, the method for manufacturing first heat radiation fins 88 is described below. A plurality of fins having L shaped cross-sections are arranged, and, a roller is used as an electrode, and an AC voltage is applied to the roller and partition plate 83, so that the plurality of fins having the L shaped cross-sections are integrated by seam welding of continuously welding central parts of short sides of the L-shapes by the roller.

FIG. 12C is a rear view illustrating a method for manufacturing heat radiation fins of the heat radiation part of the cooling device of the second exemplary embodiment of the present invention. FIG. 12C illustrates a case where the fins are formed in square wave shapes. In FIG. 12C, fixing of the fins is easier than fixing of the plurality of fins of FIG. 12B, and a number of processes of welding work can be reduced.

In a case where first heat radiation fins 88 and second heat radiation fins 91 are not integrated with the partition plate by welding, integration by screws is possible. However, when thermal resistance of connection surfaces is considered, integration by welding is preferable.

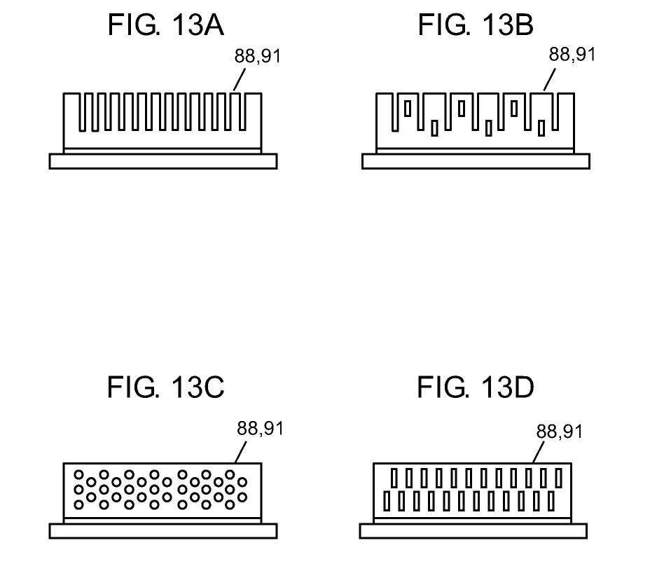

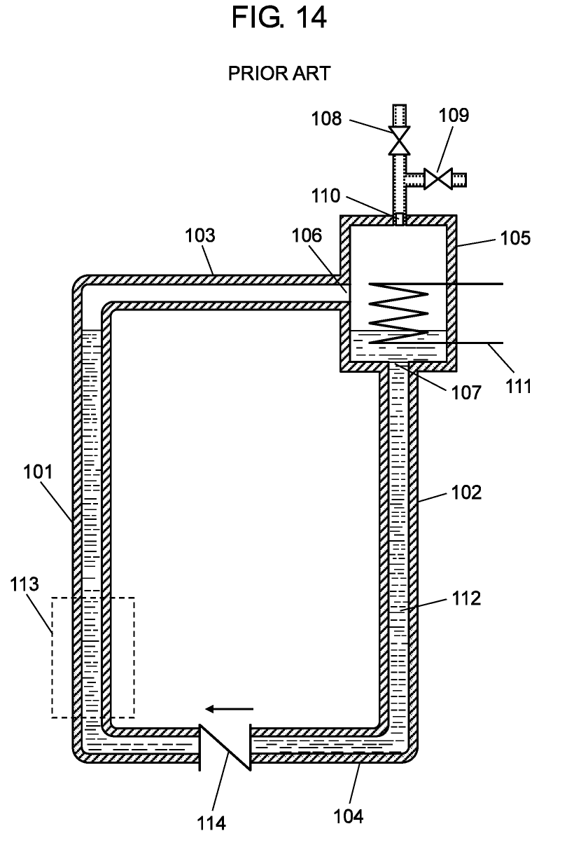

FIG. 13A to FIG. 13D are diagrams of first heat radiation fins 88, second heat radiation fins 91 of FIG. 12A to FIG. 12D, as viewed from a back surface. As a shape in a square wave height direction of a long side of the L-shape, a slit, a round hole, a square hole is used. These shapes exhibit an effect of causing vapor or cooling water flowing between first heat radiation fins 88, and between second heat radiation fins 91 to generate a turbulent flow, and improving efficiency of heat exchange with the fins. Additionally, these shapes also exhibit an effect capable of making a flow between first heat radiation fins 88 and a flow between second heat radiation fins 91 uniform.

These shapes are particularly effective shapes for heat exchange with liquid such as water of second heat radiation fins 91. However, in heat exchange with vapor of first heat radiation fins 88, when cut areas are too large, heat exchange area is reduced, and therefore such a case sometimes is not effective.

Then, a method for cooling outer cooling loop 55 that cools cooling water 79 for passing through cooling water pipe 82 to exchange heat with working fluid 67 is described with reference to FIG. 8B.

Cooled outward cooling water 78 is fed from outdoor cooling tower 7, passes through outward water cooling tube 58, and is divided into a plurality of heat radiation parts 65 from header 74a of water-cooled heat exchanger 59. Thereafter, divided cooled outward cooling water 78 converges in header 74b to circulate to return water cooling tube 60.

At this time, cooling water 79 that receives heat from vaporized working fluid 67 which flows through cooling water pipe 82 inside heat radiation part 65 becomes return cooling water 80, and passes through return water cooling tube 60 to be carried to outdoor cooling tower 7. Then, heat from heat radiation parts 65 is radiated to outside air 31, and return cooling water 80 is cooled up to an outside air temperature level.

Return cooling water 80 cooled by outdoor cooling tower 7 becomes outward cooling water 78, and outward cooling water 78 is fed to water-cooled heat exchanger 59 again to take heat from heat radiation parts 65 of inner cooling loops 56. By such circulation, electronic devices 3 are continuously cooled.

As illustrated in FIG. 8B, cooling water 79 that flows in parallel into a plurality of heat radiation parts 65 has a uniform flow rate in each heat radiation part 65. This is because respective flow passage pressure losses in passages from header 74a to header 74b through heat radiation parts 65 are made equal. As a result, all heat radiation parts 65 of water-cooled heat exchanger 59 have the same cooling performance.

Thus, in the data center provided with cooling device 54 that cools each rack type server of the second exemplary embodiment of the present invention, heat taken from heat radiation part 65 of each of inner cooling loops 56 illustrated in FIG. 9B is radiated to outside air 31 from outdoor cooling tower 7, as illustrated in FIGS. 1, 8A, and 8B. Therefore, it is possible to prevent indoor temperature rise caused by exhaust heat of cooling device 54, and increase in power consumption as a whole of data center 1 including an air conditioner is suppressed.

As described above, each of heat radiation parts 65 has partition plate 83 that partitions the inside of heat radiation case 66 into the upper and lower parts, and liquefying chamber 84 and cooling water chamber 85 that are disposed at the upper and lower parts of partition plate 83 respectively. A height of the upper end of partition plate 83 is made to be lower than a height of the lower end of second connection part 87. Consequently, condensed water can be stayed on partition plate 83 for a predetermined time, and the condensed water stayed on the partition plate is cooled up to a temperature lower than a condensation temperature, and thereafter flows to feedback passage 64. This lowering of the temperature of condensed water in each of feedback passages 64 is effective to automatically lower saturated vapor pressure (saturated vapor temperature) inside liquefying chambers 84 or heat receiving parts 62. Consequently, it is possible to enhance cooling capacity of heat receiving parts 62.

As described above, cooling device 54 of this exemplary embodiment cools rack type servers 1 each including a plurality of electronic devices 3. Additionally, cooling device 4 has a circulation passage that annularly connects heat receiving part 62, heat radiation passage 63, heat radiation part 65, and feedback passage 64 in order, and working fluid 67 housed in the circulation passage, and check valve 71 provided on an upstream side of heat receiving part 62. Heat radiation part 65 has liquefying chamber 84 and cooling water chamber 85 separated by partition plate 83. Liquefying chamber 84 has first connection part 86 connected to heat radiation passage 63 at an upper part of liquefying chamber 84, and second connection part 87 connected to feedback passage 64 at a lower part of liquefying chamber 84, and has a plurality of first heat radiation fins 88 fixed to partition plate 33, and having a plurality of openings or cutouts. Cooling water chamber 85 has cooling water inlet 89, cooling water outlet 90, and a plurality of second heat radiation fins 91 that separate a passage from cooling water inlet 89 to cooling water outlet 90 into a plurality of parallel passages. In heat radiation part 65, the inside of the heat radiation case is vertically partitioned into liquefying chamber 84 on an upper side and cooling water chamber 85 on a lower side by partition plate 83. First heat radiation fins 88 separate a passage from first connection part 86 to second connection part 87 into a plurality of parallel passages. The outer periphery of partition plate 83 is welded to the inner surface of heat radiation part 65. The upper end of partition plate 83 is located below the lower end of second connection part 87. Consequently, it is possible to lower a temperature of condensed working fluid 67 to enhance cooling capacity.

In cooling device 54 of this exemplary embodiment, first heat radiation fins 88 are integrated with partition plate 83 by welding. Second heat radiation fins 91 are integrated with partition plate 83 by welding. Consequently, it is possible to efficiently cool first heat radiation fins 88, partition plate 83, and second heat radiation fins 91.

In cooling device 54 of this exemplary embodiment, first heat radiation fins 88 and second heat radiation fins 91 are provided in substantially parallel to each other. Consequently, it is possible to effectively perform heat transfer from working fluid 67 to first heat radiation fins 88 and second heat radiation fins 91.

In cooling device 54 of this exemplary embodiment, longitudinal lengths of first heat radiation fins 88 increase toward a back side of heat radiation case 66 from first connection part 86 side. Consequently, it is possible to ensure a flow passage of working fluid 67.

Cooling device 54 of this exemplary embodiment is applicable to data center 1 provided with cooling device 4. Consequently, cooling device 54 is useful for cooling an electronic device and the like of data center 1.

### INDUSTRIAL APPLICABILITY

The cooling device of the present invention is useful for cooling of an electronic device of a data center, a semiconductor switching element or the like inside an inverter circuit of an electric vehicle.

### REFERENCE MARKS IN THE DRAWINGS

1 data center
2 rack type server
3 electronic device
3a case
4 cooling device
5 outer cooling loop
6 inner cooling loop
7 outdoor cooling tower
8 outward water cooling tube
9 water-cooled heat exchanger
10 return water cooling tube
12 heat receiving part
13 heat radiation passage
14 feedback passage
15 heat radiation part
16 heat radiation case
17 working fluid
17a flow of vapor
17b flow of vapor
19 electronic component
20 liquid level
21 check valve
22 housing
23 rear side
24a header
24b header
25a cooling water inlet pipe
25b cooling water outlet pipe
26a flexible tube
26b flexible tube
28 outward cooling water
29 cooling water
30 return cooling water
31 outside air
32 cooling water pipe
33 partition plate
34 liquefying chamber
35 cooling water chamber
36 first connection part
37 second connection part
38 first heat radiation fin
39 cooling water inlet
40 cooling water outlet
41 second heat radiation fin
54 cooling device
55 outer cooling loop
56 inner cooling loop
58 outward water cooling tube
59 water-cooled heat exchanger
60 return water cooling tube
62 heat receiving part
63 heat radiation passage
64 feedback passage
65 heat radiation part
66 heat radiation case
67 working fluid
67a lower vapor
67b upper vapor
69 electronic component
70 liquid level
71 check valve
72 housing
73 rear side
74a header
74b header
75a cooling water inlet pipe
75b cooling water outlet pipe
76a flexible tube
76b flexible tube
78 outward cooling water
79 cooling water
80 return cooling water
82 cooling water pipe
83 partition plate
84 liquefying chamber
85 cooling water chamber
86 first connection part
87 second connection part
88 first heat radiation fin
89 cooling water inlet
90 cooling water outlet
91 second heat radiation fin

1. A cooling device for cooling a rack type server including a plurality of electronic devices, the cooling device comprising:
a circulation passage that annularly connects a heat receiving part, a heat radiation passage, a heat radiation part, and a feedback passage in order;
working fluid housed in the circulation passage; and
a check valve provided on an upstream side of the heat receiving part, wherein
the heat radiation part has a liquefying chamber and a cooling water chamber separated by a partition plate,
the liquefying chamber has a first connection part connected to the heat radiation passage at an upper part of the liquefying chamber, and a second connection part connected to the feedback passage at a lower part of the liquefying chamber, and has a plurality of first heat radiation fins fixed to the partition plate and having a plurality of openings or cutouts, and
the cooling water chamber has:
a cooling water inlet;
a cooling water outlet; and
a plurality of second heat radiation fins that separate a passage from the cooling water inlet to the cooling water outlet into a plurality of parallel passages.

2. The cooling device according to claim 1, wherein
in the heat radiation part, inside of the heat radiation case is partitioned into right and left parts by the partition plate to be separated into the liquefying chamber and the cooling water chamber,
the first heat radiation fins are provided in a vertical direction of the partition plate, and incline upward from the partition plate, and
the second heat radiation fins are orthogonal to the first heat radiation fins.

3. The cooling device according to claim 2, wherein
gaps are provided between distal ends of the first heat radiation fins and an inner wall of the heat radiation part, the inner wall facing the partition plate.

4. The cooling device according to claim 2, wherein
the first heat radiation fins are integrated with the partition plate by welding, and the second heat radiation fins are integrated with the partition plate by welding.

5-10. (canceled)

11. The cooling device according to claim 3, wherein
the first heat radiation fins are integrated with the partition plate by welding, and the second heat radiation fins are integrated with the partition plate by welding.

12. A data center comprising the cooling device according to claim 1.

13. A data center comprising the cooling device according to claim 2.

14. A data center comprising the cooling device according to claim 3.

15. A data center comprising the cooling device according to claim 4.

16. A data center comprising the cooling device according to claim 11.

17. The cooling device according to claim 1, wherein
in the heat radiation part, inside of the heat radiation case is vertically partitioned into the liquefying chamber on an upper side and the cooling water chamber on a lower side by the partition plate,
the first heat radiation fins separate a passage from the first connection part to the second connection part into a plurality of parallel passages, and
an outer periphery of the partition plate is welded to an inner surface of the heat radiation part, and
an upper end of the partition plate is located below a lower end of the second connection part.

18. The cooling device according to claim 17, wherein
the first heat radiation fins are integrated with the partition plate by welding, and the second heat radiation fins are integrated with the partition plate by welding.

19. The cooling device according to claim 17, wherein
the first heat radiation fins and the second heat radiation fins are provided in substantially parallel to each other.

20. The cooling device according to claim 18, wherein
the first heat radiation fins and the second heat radiation fins are provided in substantially parallel to each other.

21. The cooling device according to claim 17, wherein
longitudinal lengths of the first heat radiation fins increase toward a back side of the heat radiation case from the first connection part.

22. The cooling device according to claim 18, wherein
longitudinal lengths of the first heat radiation fins increase toward a back side of the heat radiation case from the first connection part.

23. The cooling device according to claim 19, wherein
longitudinal lengths of the first heat radiation fins increase toward a back side of the heat radiation case from the first connection part.

24. The cooling device according to claim 20, wherein
longitudinal lengths of the first heat radiation fins increase toward a back side of the heat radiation case from the first connection part.

25. A data center comprising the cooling device according to claim 17.

26. A data center comprising the cooling device according to claim 18.
